(19) United States
(12) Patent Application Publication
(10) Pub. No.: US 2012/0040520 A1
(43) Pub. Date: Feb. 16, 2012

(54) ULTRA-FINE-GRAINED POLYSILICON THIN FILM VAPOUR-DEPOSITION METHOD

(76) Inventors: Hai Won Kim, Gyeonggi-do (KR); Sang Ho Woo, Gyeonggi-do (KR); Sung Gil Cho, Gyeonggi-do (KR)

(21) Appl. No.: 13/266,423

(22) PCT Filed: Apr. 12, 2010
(86) PCT No.: PCT/KR2010/002226

§ 371 Date: Oct. 26, 2011

(30) Foreign Application Priority Data
Apr. 28, 2009 (KR) 10-2009-0037145

(51) Int. Cl. H01L 21/20

(52) U.S. Cl. 438/488; 257/E21.09

(57) ABSTRACT

Provided is a method of depositing an ultra-fine grain polysilicon thin film. The method includes forming a nitrogen atmosphere in a chamber loaded with a substrate, and supplying a source gas into the chamber to deposit a polysilicon thin film on the substrate, in which the source gas includes a silicon-based gas, a nitrogen-based gas, and a phosphorous-based gas. The forming of the nitrogen atmosphere may include supplying a nitrogen-based gas into the chamber.

### TECHNICAL FIELD

The present invention disclosed herein relates to a method of depositing a thin film on a substrate, and more particularly, to a method of depositing a thin film by chemical vapor deposition (CVD).

### BACKGROUND ART

A semiconductor manufacturing process generally comprise a deposition process of depositing a thin film on a wafer surface, and various types of thin films including a silicon oxide, a polycrystalline silicon, and a silicon nitride are deposited on the wafer surface. The chemical vapor deposition (CVD) process in various deposition processes is forming the thin file on a substrate surface by thermal decomposition or a reaction of a gas compound, that is, desired materials are deposited on the substrate surface from gas state.

In the deposition processes, the method for deposing the polycrystalline silicon film on the wafer surface is as follows.

First, the wafer is loaded in a deposition chamber and then a thin film is deposited on the wafer by supplying a source gas in the chamber. In this time, the source gas supplied in the chamber includes silane (SiH4) and the thin film is deposited on the wafer by the source gas supplied in the chamber. In this time, the polycrystalline silicon film is deposited on the wafer by thermal decomposition of silane (SiH4).

However, by the above described deposition process, it has been difficult to deposit not only a polycrystalline silicon film having silicon crystal structure of thin thickness (less than about 400 Å) but also an uniform polycrystalline silicon film. Accordingly, when the polycrystalline silicon film is used as a floating gate electrode of a semiconductor flash memory, there are some problems such as over erase phenomenon in the manufactured device and thereby characteristics of the device such evenness, durability and reliability of the device are degraded by threshold voltage shift and very uneven threshold voltage.

More particularly, an amorphous silicon thin film is firstly grown at a constant process temperature (usually less than 55° C.) by using silane (SiH4) or disilane (Si2H6) and then the grown thin film is crystallized by a subsequent predetermined heat treatment process (for example, 650° C. to 900° C.). Consequently, results as shown in FIG. 1 is obtained. FIG. 1 is photographs of the polycrystalline silicone film according to the conventional deposition process, which are taken by a Transmission Electron Microscope (TEM).

When the gate electrode of the device such as the flash memory is formed by the above described processes, grin sizes of crystallized grains of the thin film are very irregular and crystal grains having sizes of tens of Å or few hundreds of nm are formed. Thus, when a transistor is formed by using such process, one or two grain boundaries are formed in regions where the size of grains is large, and on the contrary, many grain boundaries are formed in regions where the size of grains is very small. Therefore, in the region where crystal grains are very small and thus many grain boundaries are formed, an oxide valley region is formed by tunnel oxide under the region where the crystal grains are contacted to each other. A lager oxide valley is formed under an interface between larger crystal grains. Accordingly, more phosphorus is concentrated in the oxide valley region at the subsequent process of forming phosphorus polycrystalline silicon polycrystalline silicon so as to reduce a local barrier height. Thereby, it may cause reliability of the device to be largely degraded because the over erase point or electron trap formation site is formed by the concentrated phosphorus at the time of driving the device. That is, differences between moving speeds of electrons by the over erase or the electron trap causes differences of driving characteristics between the transistors. As a result, there are problems that characteristics of the devices including the transistors are terribly degraded because the driving characteristics of transistors included in one chip are largely different from each other when the device is driven.

### DISCLOSURE

### Technical Problem

An object of the present invention is to provide a method for depositing an ultra-fine-grained polysilicon thin film that can prevent characteristics of the device to be degraded by improving a degree of uniformity of electrical characteristics.

### Technical Solution

Embodiments of the present invention provide a method of depositing an ultra-fine grain polysilicon thin film including: forming a nitrogen atmosphere in a chamber loaded with a substrate; and supplying a source gas into the chamber to deposit a polysilicon thin film on the substrate, wherein the source gas includes a silicon-based gas, a nitrogen-based gas, and a phosphorous-based gas.

In some embodiments, the forming of the nitrogen atmosphere may include supplying a nitrogen-based gas into the chamber.

In other embodiments, the nitrogen-based gas may be ammonia (NH₃).

In still other embodiments, a mixing ratio of the nitrogen-based gas to the silicon-based gas in the source gas may be about 0.03 or less (except for 0).

In even other embodiments, nitrogen in the thin film is about 11.3 atomic percentages (%) or less (except for 0).

In yet other embodiments, the method further include a heat treatment process with respect to the thin film.

In further embodiments, the silicon-based gas may be any one of silane (SiH₄), disilane (Si₂H₆), dichlorosilane (DCS), trichlorosilane (TCS), and hexachlorosilane (HCD).

In still further embodiments, the phosphorous-based gas may be phosphine (PH₃).

In even further embodiments, the method may deposit an n+ or a p+ doped polysilicon thin film during thin film deposition.

In yet further embodiments, a polysilicon layer having ultra-fine grains may be deposited by implanting an n+ type dopant impurity such as PH₃ or arsenic (As) in-situ, when the n+ doped polysilicon thin film is deposited.

In much further embodiments, a polysilicon layer having ultra-fine grains may be deposited by implanting a p+ type dopant impurity such as boron (B) in-situ, when the p+ doped polysilicon thin film is deposited.

### Advantageous Effects

According to the method for depositing an ultra-fine-grained polysilicon thin film of the present invention, the method can prevent characteristics of the device to be degraded by improving a degree of uniformity of electrical characteristics when the thin film is deposited on a substrate using a chemical vapor desposition because the ultra-fine-grained polysilicon thin film is deposited on the substrate by feeding source gas including silicon-based gas, nitrogen-based gas and phosphorous-based gas in a chamber loaded with the substrate.

In addition, the present invention uses silane (SiH4) gas as silicon source gas and the size of crystal particles is controlled in the deposition process by mixing nitrogen-containing gas such as NH3 with SiH3 in a predetermined ratio and injecting the mixed gas under predetermined process temperature and pressure. Accordingly, when the polysilicon thin film is used as the electrode of the floating gate of the flash memory in the semiconductor device, uniform crystal grains can be formed and thereby durability and reliability of the device can be obtained. In addition, when the polysilicon thin film is used in Dynamic Random Access Memory (DRAM), Static Random Access Memory (SRAM) and LOGIC device, excellent device characteristics can be secured and thus yield and characteristics of this semiconductor device can be improved by manufacturing the device using the polysilicon thin film.

### DESCRIPTION OF DRAWINGS

FIG. 1 is a photograph illustrating a polycrystalline silicon film having a large size of grains according to a conventional deposition method.

FIG. 2 is a conceptual diagram of a thin film deposition apparatus according to the present invention.

FIG. 3 is a graph illustrating characteristics of the polysilicon thin film formed by the method for depositing the ultra-fine-grained polysilicon thin film according to the present invention, and particularly the graph shows a refractive index according to a mixing ratio of nitrogen source gas and silicon source gas.

FIG. 4 is a TEM photograph illustrating crystal structures of thin films deposited by the method for depositing the ultra-fine-grained polysilicon thin film according to the present invention.

FIGS. 5 and 6 are a table and a graph illustrating a value of converting concentration of nitrogen atomic percentage (atomic %) and grain size according to the mixing ratio of nitrogen source gas and silicon source gas.

FIG. 7 is a graph showing a threshold voltage.

### MODE FOR INVENTION

Hereinafter, preferred embodiments of the present invention will be described in details with reference to the accompanying drawings. The embodiments of the present invention can be changed in various forms and thus the present invention is not limited to the embodiments disclosed hereinafter. The embodiments are provided to assist those of ordinary skill in the art in comprehensive understanding of the present invention and thus configurations of the respective elements can be exaggerated to emphasize the feature of the present invention and explain the present invention more clearly.

According to an exemplary embodiment of the present invention, when a thin film is deposited on a substrate using a chemical vapor deposition process, an ultra-fine-grained polysilicon thin film is to be deposited by depositing the thin film on a substrate by feeding source gas including silicon-based gas, nitrogen-based gas and phosphorous-based gas in a chamber loaded with the substrate.

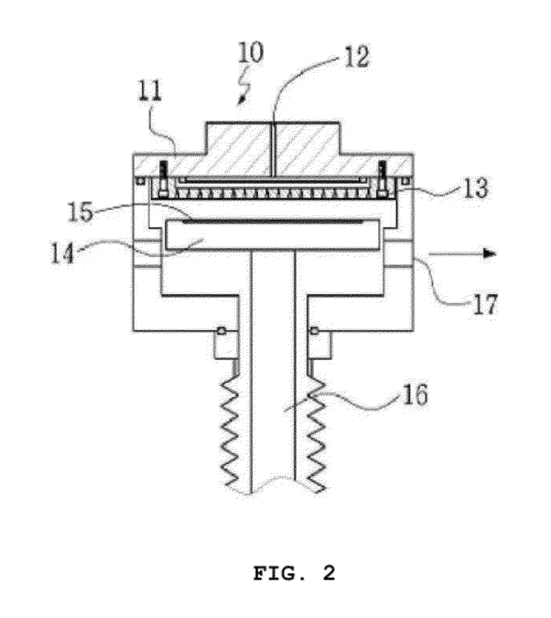

Generally, the “chemical vapor deposition” is a process of forming a thin film on a semiconductor substrate by feeding source gas in gas state to a substrate and inducing chemical reaction between the source gas and the substrate. Referring to FIG. 2, the chemical vapor deposition process performed in a single chamber according to the present invention will be explained. FIG. 2 illustrates a deposition apparatus applied to the present invention.

An inlet 12 for introducing a source gas into a chamber 11 of a deposition apparatus 10 is formed. The gas introduced by the inlet 12 is injected into the chamber 11 through a shower head 13. Also, a wafer 15, which is a subject of deposition, is disposed on a heater 14 and the heater 14 is supported by a heater support 16. Deposition is performed by the foregoing apparatus, and then the deposited substrate is discharged through a vacuum port 17.

First, a substrate is transferred to the inside of the reaction chamber 11, and then a nitrogen environment is formed in the reaction chamber 11. For example, ammonia (NH₃) is supplied to the inside of the reaction chamber 11 to maintain a nitrogen environment in the reaction chamber 11. As a result, the substrate is disposed in a nitrogen environment and is subjected to a pre-treatment in the nitrogen environment.

Thereafter, the reaction gas, in which silane (SiH₄) gas and inert N₂ as a carrier gas are flown into the chamber 11 and are decomposed by thermal decomposition, is deposited on a silicon wafer disposed on the heater through surface transfer by a single wafer-type chemical vapor deposition method. At this time, when NH₃ gas (e.g., the NH₃ gas may be the same as the NH₃ supplied during the previous pre-treatment) is introduced at a constant ratio into the reaction chamber 11 simultaneously with SiH₄ gas, grain growth caused by silicon atoms of the thermally decomposed reaction gas is delayed due to nitrogen atoms decomposed from NH₃. Therefore, deposition of amorphous polysilicon is possible even at high temperatures (a high temperature of 650° C. or more).

In the process, a mixing ratio of NH3/SiH4 gases is the most important factor in the present invention because silicon nitride can be deposited when the mixing ratio of two reaction gases is maintained over certain level.

In order to form the polycrystalline silicon having ultra-fine-grained structures, subsequent thermal treatment process is performed over a predetermined temperature using a reaction chamber of furnace type or single wafer type. In addition, undoped or doped thin film is deposited by injecting n+ doped-based impurities such as PH3 or p+ doped-based impurities such as boron.

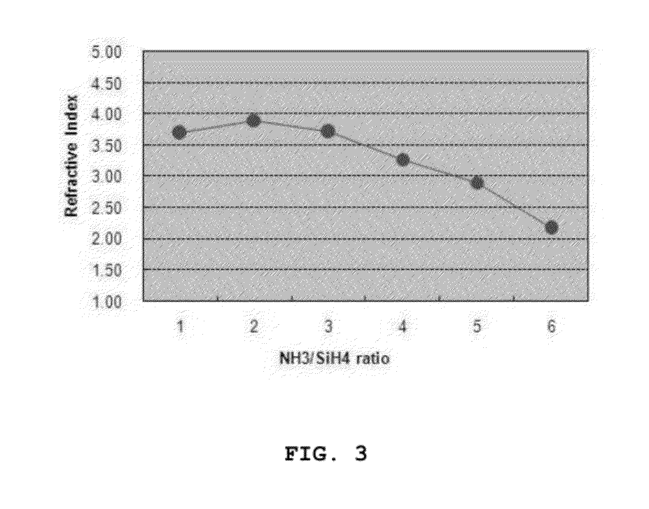

FIG. 3 is a graph showing the characteristics of a silicon thin film formed by a method of depositing an ultra-fine grain polysilicon thin film according to the present invention, and shows a refractive index with respect to a ratio between nitrogen source gas and silicon (Si) source gas.

FIG. 3 is a graph showing the variation of the refractive index according to a mixing ratio of NH₃ to SiH₄, and as shown in FIG. 3, the axis of abscissas denotes the mixing ratio of NH₃ to SiH₄, and the axis of ordinates denotes a refractive index (RI) value by which crystal characteristics of the deposited thin film may be known. Therefore, the graph shows a trend, in which the larger the ratio of NH₃ mixed in SiH₄ is, the smaller the refractive index is. When the refractive index value maintains in a range of 3.8 to 4.5, an amorphous or a polycrystalline silicon thin film may be deposited, and when the refractive index value is below the foregoing range, not a polysilicon thin film but a thin film having characteristics similar to a Si-rich Si₃N₄ thin film may be deposited.

Therefore, based on the refractive index, the mixing ratio of NH₃ to SiH₄ may be 3% (or 0.03) or less and an amorphous or a polycrystalline silicon thin film may be deposited within the foregoing range.

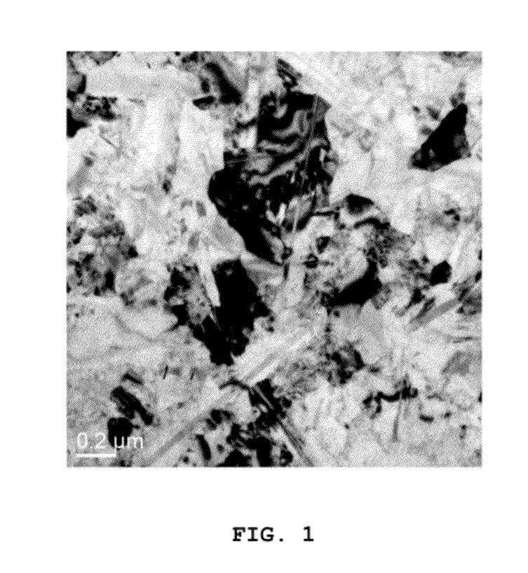

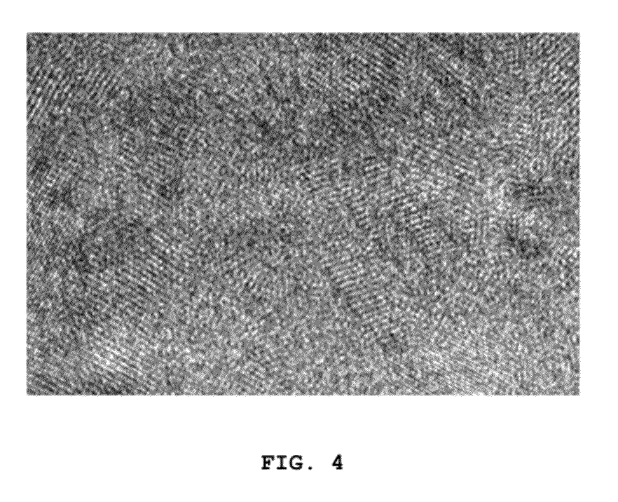

FIG. 4 is a transmission electron microscope (TEM) micrograph showing the crystal structure of a thin film deposited by the method of depositing an ultra-fine grain polysilicon thin film according to the present invention. Portions shown in black color in FIG. 4 are grains and it may be understood that the grains in FIG. 4 are finer than the grains shown in FIG. 1.

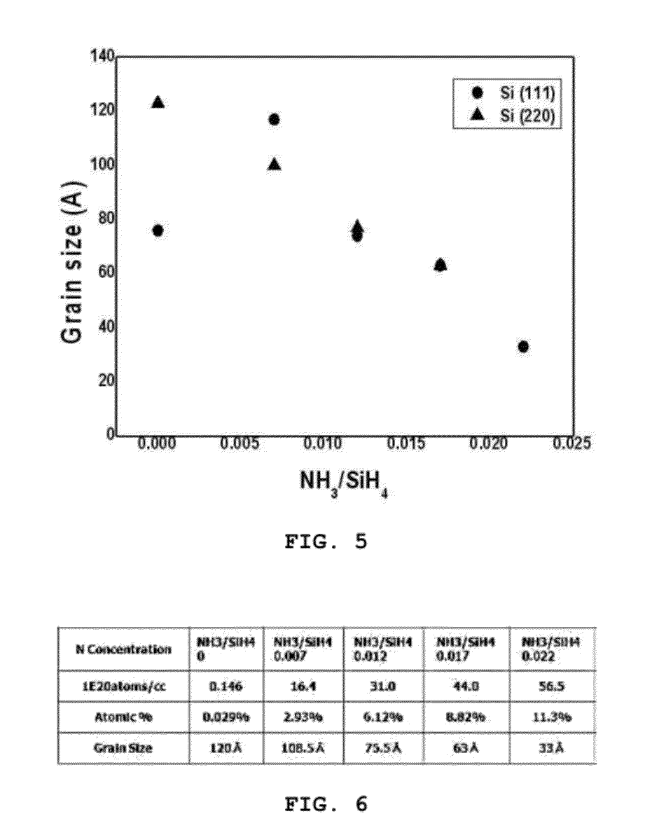

FIGS. 5 and 6 are graph and table showing the variation of grain size with respect to a gas mixing ratio between nitrogen and Si source, and values in which nitrogen concentrations are converted to atomic percentages (%), respectively.

As shown in FIGS. 5 and 6, it may be understood that nitrogen in a thin film is 11.3 at % when the foregoing mixing ratio of NH₃ to SiH₄ is 2.2% (or 0.022) and that nitrogen in the thin film may be about 11.3 at % or less according to FIGS. 5A and 5B. When nitrogen in the thin film is 11.3 at %, the grain size is about 33 Å.

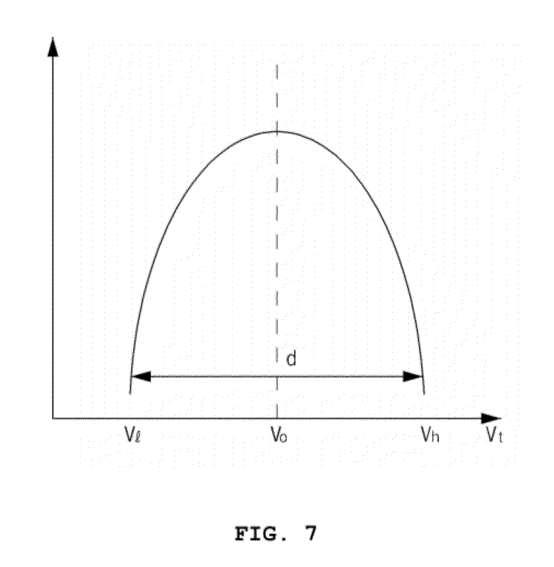

FIG. 7 is a graph showing a threshold voltage. For example, the threshold voltage (Vt) of an electrode, in which data is stored, must be constant in order for a memory cell with polysilicon deposited to be properly operated. However, the changes in distribution (d=V2−V1) may increase according to a position because the distribution of the threshold voltage is inconstant and poor. As a result, the memory cell may not be properly operated.

However, when the pre-treatment is performed in a nitrogen atmosphere as described above, nitrogen atoms, for example, are disposed between a floating gate formed of a polysilicon thin film and a tunnel oxide layer at a lower portion of the floating gate, and the nitrogen atoms prevent phosphorous (P) from moving to the tunnel oxide layer. Thus, the distribution of the threshold voltage is improved such that a constant threshold voltage may be obtained according to a position.

Although SiH₄ as a Si source and NH₃ gas as a nitrogen source are used as source gases in the present invention by using the inventive concept suggested in the present invention, that disilane (Si₂H₆), dichlorosilane (DCS), trichlorosilane (TCS), hexachlorosilane (HCD), and other Si-containing gases as another Si source gas and another nitrogen-containing gas are used and injected at a constant NH₃/SiH₄ ratio into a reaction chamber at constant temperature and pressure to form a thin film having a ultra-fine grain structure is another embodiment of the present invention.

As such, the present invention deposits the ultra-fine-grained polysilicon thin film by depositing the thin film on a substrate by feeding source gas including silicon-based gas, nitrogen-based gas and phosphorous-based gas in a chamber loaded with the substrate when the thin film is deposited by the chemical vapor deposition process.

While the invention has been described with reference to specific preferred embodiments, it will be understood by those skilled in the art that other embodiments may be possible. Therefore, the technical concept and scope of the following claims are not limited to the preferred embodiments.

1. A method of depositing an ultra-fine grain polysilicon thin film comprising:
forming a nitrogen atmosphere in a chamber loaded with a substrate; and
supplying a source gas into the chamber to deposit a polysilicon thin film on the substrate, wherein the source gas comprises a silicon-based gas, a nitrogen-based gas, and a phosphorous-based gas.

2. The method of claim 1, wherein the forming of the nitrogen atmosphere comprises supplying a nitrogen-based gas into the chamber.

3. The method of claim 2, wherein the nitrogen-based gas is ammonia (NH₃).

4. The method of claim 1, wherein a mixing ratio of the nitrogen-based gas to the silicon-based gas in the source gas is about 0.03 or less (except for 0).

5. The method of claim 1, wherein nitrogen in the thin film is about 11.3 atomic percentages (%) or less (except for 0).

6. The method of claim 1, wherein the method further comprises a heat treatment process with respect to the thin film.

7. The method of claim 1, wherein the silicon-based gas is any one of silane (SiH₄), disilane (Si₂H₆), dichlorosilane (DCS), trichlorosilane (TCS), and hexachlorosilane (HCD).

8. The method of claim 1, wherein the phosphorous-based gas is phosphine (PH₃).

9. The method of claim 1, wherein the method deposits an n+ or a p+ doped polysilicon thin film during thin film deposition.

10. The method of claim 9, wherein a polysilicon layer having ultra-fine grains is deposited by implanting an n+ type dopant impurity such as PH₃ or arsenic (As) in-situ, when the n+ doped polysilicon thin film is deposited.

11. The method of claim 9, wherein a polysilicon layer having ultra-fine grains is deposited by implanting a p+ type dopant impurity such as boron (B) in-situ, when the p+ doped polysilicon thin film is deposited.

12. The method of claim 2, wherein the method deposits an n+ or a p+ doped polysilicon thin film during thin film deposition.

13. The method of claim 3, wherein the method deposits an n+ or a p+ doped polysilicon thin film during thin film deposition.

14. The method of claim 4, wherein the method deposits an n+ or a p+ doped polysilicon thin film during thin film deposition.

15. The method of claim 5, wherein the method deposits an n+ or a p+ doped polysilicon thin film during thin film deposition.

16. The method of claim 6, wherein the method deposits an n+ or a p+ doped polysilicon thin film during thin film deposition.

17. The method of claim 7, wherein the method deposits an n+ or a p+ doped polysilicon thin film during thin film deposition.

18. The method of claim 8, wherein the method deposits an n+ or a p+ doped polysilicon thin film during thin film deposition.
